(19) United States
(12) Patent Application Publication
(10) Pub. No.: US 2025/0176141 A1
(43) Pub. Date: May 29, 2025

(54) HEAT SINK

(71) Applicant: FURUKAWA ELECTRIC CO., LTD., Tokyo (JP)

(72) Inventors: Shuta HIKICHI, Tokyo (JP); Kazuhito WATANABE, Tokyo (JP); Hiroshi SAKAI, Tokyo (JP); Yasumi SASAKI, Tokyo (JP); Masahiro MEGURO, Tokyo (JP)

(73) Assignee: FURUKAWA ELECTRIC CO., LTD., Tokyo (JP)

(21) Appl. No.: 19/036,649

(22) Filed: Jan. 24, 2025

Related U.S. Application Data
(63) Continuation of application No. PCT/JP2023/026954, filed on Jul. 24, 2023.

(30) Foreign Application Priority Data
Jul. 26, 2022 (JP) 2022-118984

(51) Int. Cl. H05K 7/20

(52) U.S. Cl. CPC H05K 7/20336

(57) ABSTRACT

A heat sink that exhibiting excellent cooling characteristics for a heat-generating element by reducing thermal resistance when heat is transferred from the heat-generating element to a heat receiving portion of a heat pipe is provided. The heat sink includes a heat pipe having a heat receiving portion adapted to be thermally connected to a heat-generating element, and a heat exchanging portion thermally connected to a heat dissipation portion of the heat pipe, wherein the heat pipe has an internal space communicating from the heat receiving portion to the heat dissipation portion, and filled with a working fluid, a section facing the heat-generating element, of the heat receiving portion is a flat segment that is flat along an extending direction of the heat-generating element, and the flat segment directly contacts the heat-generating element.

### CROSS REFERENCE TO RELATED APPLICATIONS

The present application is a continuation application of International Patent Application No. PCT/JP2023/026954 filed on Jul. 24, 2023, which claims the benefit of Japanese Patent Application No. 2022-118984, filed on Jul. 26, 2022. The contents of these applications are incorporated herein by reference in their entirety.

### BACKGROUND

### Technical Field

The present disclosure is related to a heat sink configured to cool a heat-generating element as a cooling target by transporting heat of the heat-generating element to a heat exchanging portion by using a heat transporting function of a heat pipe.

### Background

Many components including heat-generating elements such as electronic components are being installed inside electronic devices at increasingly high densities due to enhancement of functionality of the electronic devices in recent years. Heat generation in the heat-generating elements, such as electronic components, are increasing due to enhancements in functionality of the electronic devices. A heat sink may be used as a unit configured to cool heat-generating elements, such as, electronic components. To reliably cool the heat-generating elements generating large amounts of heat and disposed in relatively narrow spaces, a heat sink configured to cool a heat-generating element by using the heat transporting function of the heat pipes with the heat pipes being thermally connected to the heat-generating element as the cooling target may be used.

As the heat sink in which a plurality of heat pipes are thermally connected to a heat-generating element, there is provided, for example, a heat sink in which a plurality of radiating fins orthogonal to an axial direction of the heat pipes are arranged at one end portion of the heat pipes parallel to one another at predetermined intervals, and air is moved in a fixed direction to gaps among the radiating fins to expel heat from the radiating fins, wherein a flat plate portion is provided at an upper end in a direction orthogonal to an air movement direction, of each of the radiating fins, and a ventilation hole is provided in the flat plate portion as taught in Japanese Patent Laid-Open No. 2003-229523 (JP2003229533).

In JP2003229533, because of the ventilation hole being provided in the flat plate portion of the radiating fin, the heat exchange rate by air among the respective radiating fins is improved, and heat dissipation efficiency of the heat sink is improved. In JP2003229533, the other end portion of the heat pipe is fitted in a recessed portion formed on a front surface of a flat plate-like heat receiving block, and thereby contacted and fixed to the heat receiving block. The heat-generating element as a cooling target is connected to the back surface of the heat receiving block. In JP2003229533, stability of thermal connection between the other end portion of the heat pipe and the heat-generating element is obtained by using the heat receiving block. Therefore, in JP2003229533 the other end portion of the heat pipe is thermally connected to the heat-generating element as the cooling target via the heat receiving block. From the above, the heat generated from the heat-generating element is transferred to the heat receiving block first and further transferred from the heat receiving block to the other end portion of the heat pipe.

However, in JP2003229533, the heat receiving portion of the heat pipe is thermally connected to the heat-generating element via the heat receiving block, and hence thermal resistance when the heat is transferred from the heat-generating element to the heat receiving portion of the heat pipe is increased. In order to stably fix the other end portion of the heat pipe to the heat receiving block, the other end portion of the heat pipe is soldered to the recessed portion of the heat receiving block, and hence the thermal resistance when the heat is transferred from the heat receiving block to the other end portion of the heat pipe increases due to existence of the solder layer. Therefore, improvement is required in terms of cooling characteristics of the heat sink in JP2003229533.

Further, it is necessary to separately prepare the heat receiving block in JP2003229533, which increases the number of components.

### SUMMARY

The present disclosure is related to providing a heat sink that can also exhibit excellent cooling characteristics to a heat-generating element with high heat generation characteristics by reducing thermal resistance when heat is transferred from the heat-generating element to a heat-receiving portion of a heat pipe.

A configuration of the present disclosure is as follows.
A heat sink including a heat pipe having a heat receiving portion adapted to be thermally connected to a heat-generating element, and a heat exchanging portion thermally connected to a heat dissipation portion of the heat pipe,
wherein the heat pipe has an internal space communicating from the heat receiving portion to the heat dissipation portion, and filled with a working fluid,
a section facing the heat-generating element, of the heat receiving portion is a flat segment that is flat along an extending direction of the heat-generating element, and
the flat segment directly contacts the heat-generating element.

The heat sink wherein the flat segment extends along a heat transport direction of the heat pipe and a radial direction of the heat pipe.

The heat sink wherein the flat segment has a cut portion that is cut.

The heat sink wherein as a result of the cut portion extending to a corner portion in a radial direction of the heat pipe, at least a part of a rounded portion formed at the corner portion is cut.

The heat sink wherein the heat receiving portion has a flattened portion of which a sectional shape in an orthogonal direction to a heat transport direction of the heat pipe is a flat, and which has a height direction and a thickness direction, and of the flattened portion, a section in the thickness direction has the flat segment.

The heat sink wherein the flat segment of the section in the thickness direction of the flattened portion has a cut portion that is cut.

The heat sink wherein a plurality of the heat pipes are provided, the plurality of the heat pipes are disposed along a radial direction of the heat pipes, and the flat segments of the plurality of the heat pipes are disposed on a same plane, in the heat receiving portions.

The heat sink wherein a plurality of the heat pipes are provided, the plurality of the heat pipes are disposed along the radial direction of the heat pipes in the heat receiving portions, and the heat pipes which are adjacent directly contact each other in the heat receiving portions.

The heat sink wherein all of the flat segments of the plurality of the heat pipes directly contact the heat-generating element.

The heat sink wherein a plurality of the heat pipes are provided, the plurality of the heat pipes include a first heat pipe in which a sectional shape in a radial direction in the heat receiving portion is a first shape, and a second heat pipe in which a sectional shape in a radial direction in the heat receiving portion is a second shape that is different from the first shape.

The heat sink wherein heat transport characteristics of the first heat pipe are higher than heat transport characteristics of the second heat pipe.

The heat sink wherein a heat receiving portion of the first heat pipe and a heat receiving portion of the second heat pipe are disposed along a radial direction of the heat pipe, and the heat receiving portion of the first heat pipe is disposed in a more outward direction than the heat receiving portion of the second heat pipe.

The heat sink wherein the heat pipe has a bent portion that is bent in a direction to be away from the flat segment, in a section that is other than the heat receiving portion and extends in a longitudinal direction of the heat pipe from the heat receiving portion.

In an aspect of the heat sink, the section facing the heat-generating element, of the heat receiving portion of the heat pipe is the flat segment that is flat along the extending direction of the heat-generating element, and as a result of the flat segment directly contacting the heat-generating element, the heat-generating element can be stably contacted to the flat segment of the heat receiving portion. As a result, stability of thermal connection between the heat receiving portion of the heat pipe and the heat-generating element can be obtained without aid of a heat receiving block. Therefore, according to the aspect of the heat sink of the present disclosure, thermal resistance when the heat is transferred from the heat-generating element to the heat receiving portion of the heat pipe can be reduced, and hence excellent cooling characteristics can also be exhibited to the heat-generating element with a high heat generation amount.

According to an aspect of the heat sink of the present disclosure, the flat segment extends along the heat transporting direction of the heat pipe and the radial direction of the heat pipe, and hence stability of the thermal connection between the heat receiving portion of the heat pipe and the heat-generating element can be obtained in a more reliable manner.

According to an aspect of the heat sink of the present disclosure, as a result of the flat segment having the cut portion that is cut, flatness of the flat segment is further improved, and the thermal resistance when the heat is transferred from the heat-generating element to the heat receiving portion of the heat pipe can be further reduced. When the flat segment of the heat pipe is cut, a cutting mark is formed on the flat segment, and hence the presence or absence of the cut portion can be observed with the naked eye.

In flattening for forming the flat segment, a rounded portion is formed at the corner portion of the flat segment in the radial direction of the heat pipe. According to an aspect of the heat sink of the present disclosure, as a result of the cut portion of the flat segment extending to the corner portion in the radial direction of the heat pipe, and at least a part of the rounded portion formed at the corner portion being cut, the area ratio of the flat segment increases in the section facing the heat-generating element, of the heat receiving portion. Therefore, the thermal resistance when the heat is transferred from the heat-generating element to the heat receiving portion of the heat pipe can be further reduced.

According to an aspect of the heat sink of the present disclosure, the heat receiving portion has a flattened portion of which a sectional shape in the orthogonal direction to the heat transporting direction of the heat pipe is flat, and which has in the height direction and in the thickness direction, and of the flattened portion, the section in the thickness direction has the flat segment. Therefore, many heat pipes can be thermally connected to the heat-generating element as the cooling target without increasing the installation space of the heat receiving portion of the heat sink.

According to an aspect of the heat sink of the present disclosure, a plurality of the heat pipes are provided, the plurality of the heat pipes are disposed along the radial direction of the heat pipes, and the flat segments of the plurality of the heat pipes are disposed on the same plane, in the heat receiving portions of the heat pipe. As a result, even when the plurality of the heat pipes is provided, stability of thermal connection between the heat receiving portions of the plurality of the heat pipes and the heat-generating element can be obtained. Therefore, the thermal resistance when the heat is transferred from the heat-generating element to the heat receiving portions of the plurality of heat pipes can be reduced.

According to an aspect of the heat sink of the present disclosure, the plurality of the heat pipes is provided, the plurality of the heat pipes is disposed along the radial direction of the heat pipes in the heat receiving portions, and the heat pipes which are adjacent directly contact each other in the heat receiving portions. Therefore, the heat receiving portions of the plurality of heat pipes can transfer heat to each other, and hence the thermal load on the plurality of heat pipes can be equalized.

According to an aspect of the heat sink of the present disclosure, all the flat segments of the plurality of the heat pipes directly contact the heat-generating element. Therefore, the thermal resistance when the heat is transferred from the heat-generating element to the heat receiving portion of the heat pipe can be further reduced, with respect to all the plurality of heat pipes.

According to an aspect of the heat sink of the present disclosure, the plurality of the heat pipes include the first heat pipe in which the sectional shape in the radial direction in the heat receiving portion is a first shape, and the second heat pipe in which the sectional shape in the radial direction in the heat receiving portion is a second shape that is different from the first shape. As a result, it is possible to adjust the difference of the heat transport characteristics of the first heat pipe and the second heat pipe. Therefore, according to the aspect of the above-described heat sink, of the present disclosure, even when the temperature irregularities such as hot spots occur to the heat-generating element, excellent cooling characteristics can be exhibited to the heat-generating element.

According to an aspect of the heat sink of the present disclosure, the heat pipe has the bent portion that is bent in the direction to be away from the flat segment, in the section that is other than the heat receiving portion and extends in the longitudinal direction of the heat pipe from the heat receiving portion. As a result, even when the heat-generating element is installed in a narrow space, the heat pipe can stretch to a section other than the heat receiving portion while avoiding the narrow space. Therefore, according to the aspect of the above-described heat sink of the present disclosure, excellent cooling characteristics can also be exhibited to the heat-generating element provided in the narrow space.

### BRIEF DESCRIPTION OF THE DRAWINGS

FIG. 1 is a perspective view of a heat sink according to a first embodiment of the present disclosure.

FIG. 2 is a plan view of the heat sink according to the first embodiment of the present disclosure.

FIG. 3 is a front view of the heat sink according to the first embodiment of the present disclosure viewed from one end portion direction of the heat sink.

FIG. 4 is an explanatory view illustrating an outline of a bottom surface of one end portion of the heat sink according to the first embodiment of the present disclosure.

FIG. 5 is an explanatory view illustrating a sectional shape in a radial direction of a heat pipe included in the heat sink according to the first embodiment of the present disclosure;

FIG. 6 is an explanatory view illustrating an outline of one end portion of a heat sink according to a second embodiment of the present disclosure from a front direction.

FIG. 7 is an explanatory view illustrating an outline of one end portion of a heat sink according to a third embodiment of the present disclosure from a front direction.

FIG. 8 is an explanatory view illustrating an outline of a bottom surface of one end portion of a heat sink according to a fourth embodiment of the present disclosure.

FIG. 9 is an explanatory view illustrating a stretching state of a heat pipe included in the heat sink according to the fourth embodiment of the present disclosure.

FIG. 10 is an explanatory view illustrating a state before forming a flat segment in a heat receiving portion of a heat pipe included in a heat sink.

FIG. 11 is an explanatory view of the heat sink of the present disclosure, illustrating a state after the flat segment is formed in the heat receiving portion of the heat pipe included in the heat sink.

### DETAILED DESCRIPTION

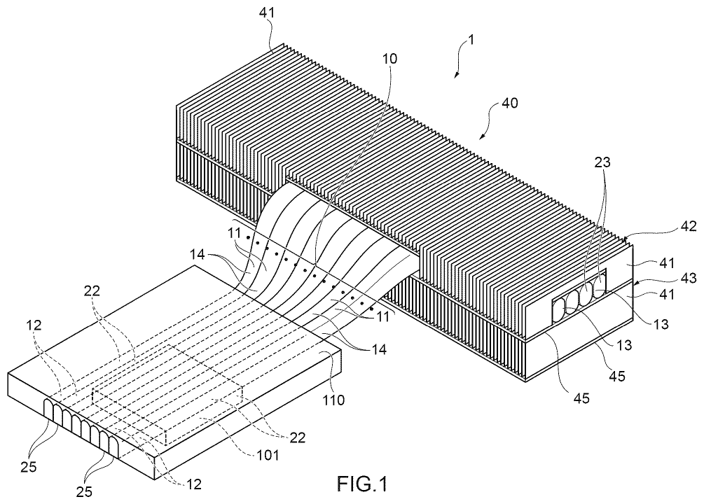

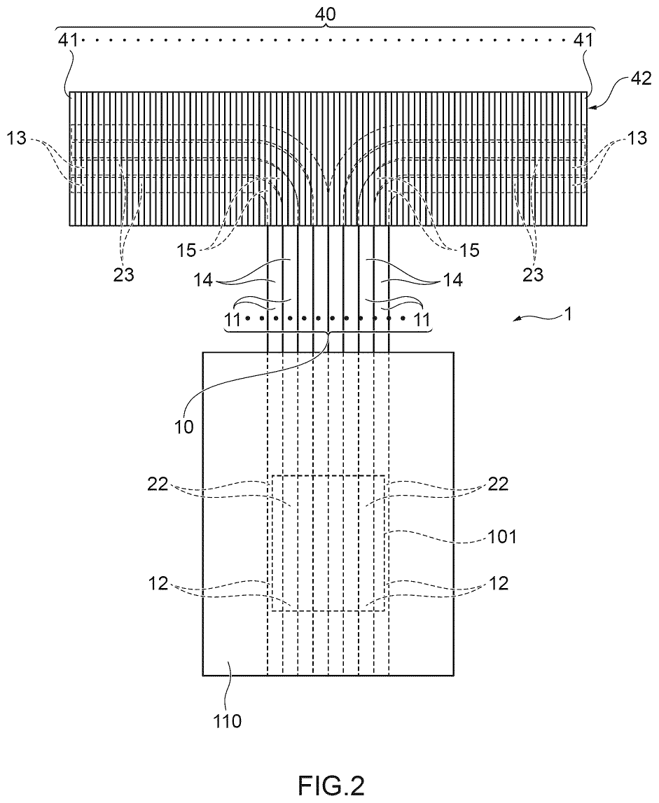

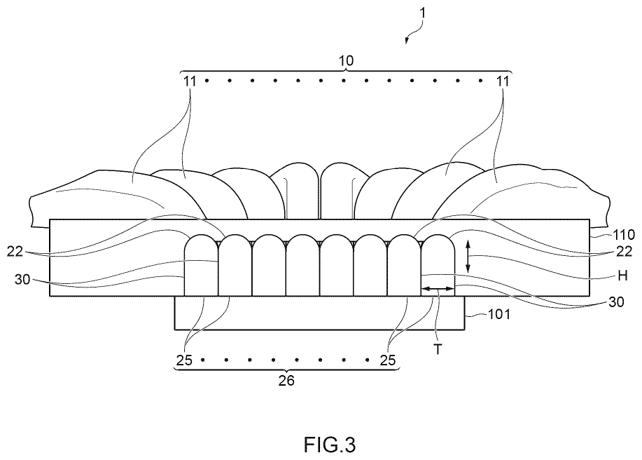

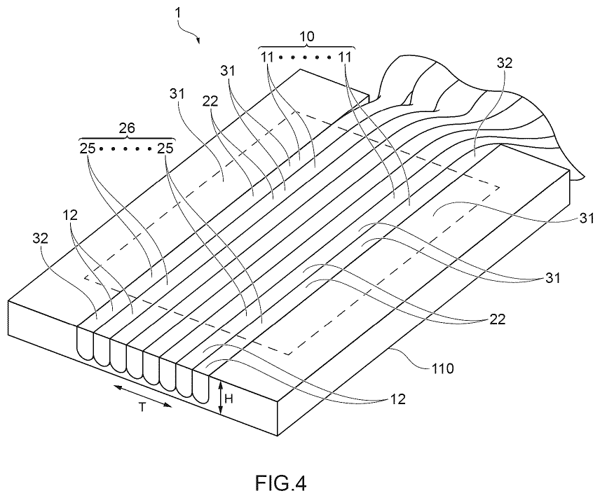

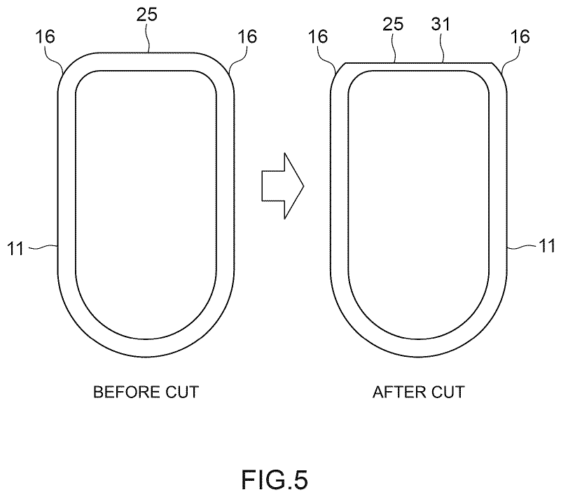

Hereinafter, a heat sink according to a first embodiment of the present disclosure will be described with reference to the accompanying drawings. FIG. 1 is a perspective view of the heat sink according to the first embodiment of the present disclosure. FIG. 2 is a plan view of the heat sink according to the first embodiment of the present disclosure. FIG. 3 is a front view of the heat sink according to the first embodiment of the present disclosure, viewed from one end portion direction. FIG. 4 is an explanatory view illustrating an outline of a bottom surface of one end portion of the heat sink according to the first embodiment of the present disclosure. FIG. 5 is an explanatory view illustrating a sectional shape in a radial direction of a heat pipe included in the heat sink according to the first embodiment of the present disclosure.

As illustrated in FIGS. 1 and 2, a heat sink 1 according to the first embodiment includes a heat pipe 11 having a heat receiving portion (evaporation portion) 22 to be thermally connected to a heat-generating element 101 as a cooling target of the heat sink 1, and a heat exchanging portion 40 thermally connected to a heat dissipation portion (condensation portion) 23 of the heat pipe 11. Several heat pipes which may include one or more, and in the heat sink 1, a plurality (eight) of heat pipes 11, 11, 11 . . . are included. The heat exchanging portion 40 is formed by a plurality of radiating fins 41 being parallelly disposed.

The heat pipe 11 is a heat transporting member in which an internal space of the heat pipe 11 is airtight and further depressurized. The internal space of the heat pipe 11 communicates from the heat receiving portion 22 to the heat dissipation portion 23 and is filled with a working fluid (not illustrated).

The plurality of heat pipes 11, 11, 11 . . . are each thermally connected to the heat-generating element 101 in one end portion 12 and thermally connected to the heat exchanging portion 40 in another end portion 13. Therefore, in each of the plurality of heat pipes 11, 11, 11 . . . , end portion 12 functions as the heat receiving portion 22, and the other end portion 13 functions as the heat dissipation portion 23. In each of the plurality of heat pipes 11, 11, 11 . . . , a longitudinal direction connecting end portion 12 and the other end portion 13 is a heat transporting direction of the heat pipe 11. In the heat sink 1, a heat pipe group 10 is formed by the plurality of heat pipes 11, 11, 11. . . . In the heat pipe group 10, the respective heat pipes 11 are parallelly disposed along a radial direction of the heat pipes 11. In the heat sink 1, the respective heat pipes 11 are parallelly disposed in a row.

Heat receiving portions 22, 22, 22 . . . of the plurality of heat pipes 11, 11, 11 . . . are parallelly disposed in a row along an extending direction of the heat-generating element 101. From the above, the one end portions 12 of the heat pipes 11 are parallelly disposed in a row along the extending direction of the heat-generating element 101. End portions 12, 12, 12 . . . of the plurality of heat pipes 11, 11, 11 . . . are parallelly disposed in a row on a substantially same plane. In the heat sink 1, a cover member 110 is mounted to cover top surfaces of the one end portions 12, 12, 12 . . . of the plurality of heat pipes 11, 11, 11 . . .

As illustrated in FIG. 2, in the heat pipe 11, a shape in plan view of the end portion 12 is substantially rectilinear, and a shape in plan view of a center portion (heat insulating portion) 14 positioned between the end portion 12 and the other end portion 13 is also substantially rectilinear. The center portion 14 of the heat pipe 11 is a section where heat does not actively enter or exit. Therefore, in the heat pipe group 10, sections that are substantially rectilinear in plan view are disposed side by side from end portion 12 through the center portions 14 of the heat pipes 11.

In the heat sink 1, with respect to the heat pipe 11, a bent portion 15 in a longitudinal direction of the heat pipe 11 is formed at the other end portion 13 thermally connected to the heat exchanging portion 40. Therefore, each of the plurality of heat pipes 11, 11, 11 . . . has a substantially L-shape in plan view. The bent portion 15 of the heat pipe 11 positioned on the right side is a rightward bend, whereas the bent portion 15 of the heat pipe 11 positioned on the left side is a leftward bend. In other words, bending directions of the bent portions 15 are opposite, with respect to the heat pipe 11 positioned on the left side and the heat pipe 11 positioned on the right side.

An aspect in which in each of the plurality of heat pipes 11, 11, 11 . . . , the other end portion 13 extends in a substantially parallel direction to the longitudinal direction of the heat exchanging portion 40 by the bent portion 15 is provided. In the heat exchanging portion 40, a plurality of radiating fins 41, 41, 41 . . . are parallelly disposed so that main surfaces (planar surface portions) of the radiating fins 41 are disposed in a substantially parallel direction to a stretching direction of the one end portions 12 of the heat pipes 11. The radiating fin 41 is a thin member having a flat plate-like shape. In the heat sink 1, the other end portion 13 of the heat pipe 11, which extends in the parallel direction to the longitudinal direction of the heat exchanging portion 40 reaches an end portion in the longitudinal direction of the heat exchanging portion 40.

As illustrated in FIGS. 1 and 2, an external shape of the heat exchanging portion 40 is substantially a rectangular parallelepiped. The heat exchanging portion 40 has a structure in which a first radiating fin group 42 having an external shape that is substantially a rectangular parallelepiped, and a second radiating fin group 43 adjacent to the first radiating fin group 42 and having an external shape that is substantially a rectangular parallelepiped are stacked. The first radiating fin group 42 and the second radiating fin group 43 each have a structure in which the plurality of radiating fins 41, 41, 41 . . . that are mounted on a flat plate-like support body 45 are parallelly disposed in a substantially parallel direction to the longitudinal direction of the heat exchanging portion 40.

The other end portion 13 of the heat pipe 11 is inserted between the first radiating fin group 42 and the second radiating fin group 43. As a result of the other end portion 13 being disposed between the first radiating fin group 42 and the second radiating fin group 43, the heat exchanging portion 40 and the heat pipe 11 are thermally connected.

As illustrated in FIGS. 3 and 4, in the heat sink 1, of the heat receiving portion 22 of the heat pipe 11, a section facing the heat-generating element 101 is a flat segment 25 that is flat along the extending direction of the heat-generating element 101. The flat segment 25 extends planarly in the heat transporting direction of the heat pipe 11 and the radial direction of the heat pipe 11. In the heat sink 1, flat segment 25 is a flat surface, and therefore can directly contact the heat-generating element 101. In the heat sink 1, flat segment 25 of the heat pipe 11 directly contacts the heat-generating element 101.

In the heat sink 1, in the heat pipe group 10 formed by the plurality of heat pipes 11, 11, 11 . . . , the plurality of heat pipes 11, 11, 11 . . . are parallelly disposed along the radial direction of the heat pipes 11, in the heat receiving portions 22 of the heat pipes 11. Flat segments 25, 25, 25 . . . of the plurality of heat pipes 11, 11, 11 . . . are disposed on the same plane. Therefore, the heat pipe group 10 has a flat region 26 where the plurality of flat segments 25, 25, 25 . . . extend continuously on the same plane.

In the heat sink 1, the adjacent heat pipes 11 directly contact each other in the heat receiving portions 22. In other words, in the heat receiving portions 22, a side surface forming the longitudinal direction of the heat pipe 11 directly contacts a side surface forming the longitudinal direction of another adjacent heat pipe 11. In the heat sink 1, the flat segments 25 of the adjacent heat pipes 11 directly contact each other at corner portions of the flat segments 25. From the above, in flat region 26 of the heat pipe group 10, the plurality of flat segments 25, 25, 25 . . . continue on the same plane, and provide essentially one connected flat surface.

As illustrated in FIGS. 3 and 4, in the heat sink 1, in the heat receiving portion 22 of the heat pipe 11, a sectional shape in the orthogonal to the heat transporting direction of the heat pipe 11 is a flat shape. In other words, the heat receiving portion 22 of the heat pipe 11 has a flattened portion 30 having a flat shape having a height direction H and a thickness direction T having a dimension smaller than a dimension in the height direction H, and of the flattened portion 30, a section in the thickness direction T is the flat segment 25. A side surface forming the longitudinal direction of the heat pipe 11 is a section in the height direction H of the flattened portion 30, and the section in the height direction H of the flattened portion 30 of the heat pipe 11 directly contacts a section in a height direction H of a flattened portion 30 of another adjacent heat pipe 11. In the heat receiving portions 22, 22, 22 . . . of the plurality of heat pipes 11, 11, 11 . . . , sectional shapes in the radial direction of the heat receiving portions 22, 22, 22 . . . are all substantially the same.

As illustrated in FIG. 4, after flattening the heat pipe 11 for forming the flat segment 25, cutting may be further applied to the flat segment 25, and a cut portion 31 may be formed, as necessary. As a result of flat segment 25 having the cut portion 31 that is a cut region, the flatness of flat segment 25 is further improved. In the heat sink 1, cutting is applied to flat segment 25, and therefore, the flat segment 25 has the cut portion 31. In the heat sink 1, cutting is applied to flat segment 25, after the heat pipe group 10 in which the plurality of heat pipes 11, 11, 11 . . . are parallelly disposed is formed. The cut portion 31 has a cutting mark formed on the cut portion 31 and has characteristics such as being glossy as compared with a section (noncut portion) 32 that is not cut.

In the heat sink 1, of the flattened portion 30, the section in the thickness direction T has the flat segment 25, and therefore the section in the thickness direction T of the flattened portion 30 has the cut portion 31 that is cut. The cut portion 31 may be formed on the entire flat segment 25, or the cut portion 31 may be formed only in a partial region of the flat segment 25, for example, a section to which the heat-generating element 101 is thermally connected and a vicinity of the section (section to which the heat-generating element 101 directly contacts and a vicinity of the section), of the flat segment 25. The lower the flatness of the cut portion 31, the better in terms of thermal connectivity of the flat segment 25 and the heat-generating element 101 being improved. The flatness is a value obtained by contact three-dimensional measurement.

In FIG. 4, for convenience of explanation, an aspect in which the cut portion 31 is formed only in the section to which the heat-generating element is thermally connected and the vicinity of the section, of flat segment 25 is provided. On a bottom surface of the cover member 110, the cut portion 31 may be formed or the cut portion 31 may not be formed, but in FIG. 4, for convenience of explanation, an aspect in which the cut portion 31 extends to a partial region of the bottom surface of the cover member 110 continuously with the cut portion 31 of the heat pipe 11, of the bottom surface of the cover member 110 positioned on the same plane as the flat segment 25 is provided. Therefore, even when the heat-generating element thermally connected to the flat segment 25 of the heat pipe 11 has such a large dimension as to extend to the cover member 110, thermal connectivity of the flat segment 25 of the heat pipe 11 and the heat-generating element is excellent.

As illustrated in FIG. 5, in flattening for forming flat segment 25 in the heat pipe 11, a rounded portion is formed at a corner portion 16 of flat segment 25 in the radial direction of the heat pipe 11. However, in the heat sink 1, because of the cut portion 31 extending to the corner portion 16 in the radial direction of the heat pipe 11, at least a part of the rounded portion formed at the corner portion 16 is cut. Therefore, of the rounded portion formed at the corner portion 16 of the heat pipe 11, at least a part of the rounded portion close to the flat segment 25 is flattened. From the above, in the heat pipe 11, the flat segment 25 is enlarged in width by forming the cut portion 31.

A wall thickness of a container of the heat pipe 11 is appropriately selectable according to a use situation or the like of the heat sink 1. Since the cut portion 31 is formed at flat segment 25 of the heat pipe 11, the cut portion 31 of the flat segment 25 is slightly thinner as compared with the noncut portion 32 of the heat pipe 11.

The heat-generating element 101 can be thermally connected to flat segment 25 of the heat pipe 11. The heat sink 1 provides an aspect in which all flat segments 25, 25, 25 . . . of the plurality of heat pipes 11, 11, 11 . . . directly contact the heat-generating element 101, and the heat-generating element 101 is thermally connected to the flat segment 25 of the heat pipe 11.

A material of the container used for the heat pipe 11 is not particularly limited, and for example, copper, copper alloy, aluminum, aluminum alloy, stainless steel and the like can be listed. The working fluid to be filled in the container of the heat pipe 11 is appropriately selectable according to adaptability with the material of the container, and for example, water, fluorocarbons, cyclopentane, ethylene glycol, mixtures of these substances, and the like can be listed. The material the radiating fin 41 is composed of is not particularly limited, and may comprise metal, such as copper and copper alloy can be listed as an example.

Next, a use method for the heat sink 1 according to the first embodiment will now be described. The heat pipe group 10 of the heat sink 1 is installed directly on the heat-generating element 101 and a vicinity of the heat-generating element 101 so that all the flat segments 25, 25, 25 . . . of the plurality of heat pipes 11, 11, 11 . . . directly contact the heat-generating element 101. Heat released from the heat-generating element 101 is directly transferred to the flat segment 25 formed at the one end portion 12 of the heat pipe 11. At this time, flat segment 25 functions as the heat receiving portion 22 of the heat pipe 11. The heat transferred to the one end portion 12 of the heat pipe 11 is transported from the one end portion 12 of the heat pipe 11 to the other end portion 13 of the heat pipe 11 by the heat transporting action of the heat pipe 11. The heat transported to the other end portion 13 of the heat pipe 11 is transferred from the other end portion 13 of the heat pipe 11 to the heat exchanging portion 40 having the plurality of radiating fins 41. At this time, the other end portion 13 of the heat pipe 11 functions as the heat dissipation portion. The heat transferred to the heat exchanging portion 40 is released to an external environment of the heat sink 1 from the heat exchanging portion 40 by a heat exchanging action (heat dissipating action) of the heat exchanging portion 40, and thereby he heat-generating element 101 can be cooled.

As a result of the section facing the heat-generating element 101, of the heat receiving portion 22 of the heat pipe 11 being the flat segment 25 that is flat along the extending direction of the heat-generating element 101 as described above, the heat-generating element 101 can be stably connected to the flat segment 25 of the heat receiving portion 22. Therefore, stability of thermal connection between the heat receiving portion 22 of the heat pipe 11 and the heat-generating element 101 is obtained without aid of a heat receiving block. Therefore, in the heat sink 1, because of the thermal resistance when the heat is transferred from the heat-generating element 101 to the heat receiving portion 22 of the heat pipe 11 being able to be reduced, excellent cooling characteristics can also be exhibited to the heat-generating element 101 having a high heat generation amount. In the heat sink 1, it is not necessary to additionally prepare a connecting/fixing member for the heat pipe 11, such as a heat receiving block. Therefore, several components can be reduced, and manufacturing cost of the heat sink 1 can be suppressed.

Especially in the heat sink 1, the flat segment 25 extends along the heat transporting direction of the heat pipe 11 and the radial direction of the heat pipe 11, and hence stability of thermal connection between the heat receiving portion 22 of the heat pipe 11 and the heat-generating element 101 can be obtained in a more reliable manner.

In the heat sink 1, as a result of the flat segment 25 of the heat receiving portion 22 being directly contacting the heat-generating element 101, stability of thermal connection between the heat receiving portion 22 and the heat-generating element 101 can be obtained, and thermal resistance when the heat is transferred from the heat-generating element 101 to the heat receiving portion 22 can be reduced. As a result, excellent cooling characteristics can be exhibited to the heat-generating element 101.

In the heat sink 1, as a result of the flat segment 25 having the cut portion 31 having flatness that is further improved, thermal connectivity between the heat-generating element 101 and the heat receiving portion 22 of the heat pipe 11 is further improved, and hence thermal resistance when the heat is transferred from the heat-generating element 101 to the heat receiving portion 22 of the heat pipe 11 can be further reduced. In the heat sink 1, the cut portion 31 of the flat segment 25 extends to the corner portion 16 in the radial direction of the heat pipe 11, and at least a part of the rounded portion formed at the corner portion 16 is cut and flattened. Therefore, in the section facing the heat-generating element 101, of the heat receiving portion 22, an area ratio of the flat segment 25 increases, and the thermal resistance when the heat is transferred from the heat-generating element 101 to the heat receiving portion 22 can be reduced in a more reliable manner.

In the heat sink 1, the heat receiving portion 22 of the heat pipe 11 has the flattened portion 30 in which the sectional shape in the orthogonal direction to the heat transporting direction of the heat pipe 11 is flat, and, of the flattened portion 30, the section in the thickness direction T has the flat segment 25. Therefore, many heat pipes 11 can be thermally connected to the heat-generating element 101 as the cooling target without increasing an installation space for the heat sink 1. Therefore, in the heat sink 1, excellent cooling characteristics can be exhibited even for the heat-generating element 101 installed in a narrow space.

In the heat sink 1, as a result of the flat segments 25, 25, 25 . . . of the plurality of heat pipes 11, 11, 11 . . . being disposed on the same plane, stability of thermal connection between the heat receiving portions 22, 22, 22 . . . of the plurality of heat pipes 11, 11, 11 . . . and the heat-generating element 101 can be obtained even when the plurality of heat pipes 11, 11, 11 . . . are provided. Therefore, the thermal resistance when the heat is transferred from the heat-generating element 101 to the heat receiving portions 22, 22, 22 . . . of the plurality of heat pipes 11, 11, 11 . . . can be reduced, and thermal load on the plurality of heat pipes 11, 11, 11 . . . can be equalized.

In the heat sink 1, the heat receiving portions 22, 22, 22 . . . of the plurality of heat pipes 11, 11, 11 . . . are parallelly disposed along the radial direction of the heat pipes 11, and the adjacent heat pipes 11 directly contact each other at the heat receiving portions 22. Therefore, the heat receiving portions 22, 22, 22 . . . of the plurality of heat pipes 11, 11, 11 . . . can transfer heat mutually, and hence the thermal load on the plurality of heat pipes 11, 11, 11 . . . can be equalized.

In the heat sink 1, as a result of all of the flat segments 25, 25, 25 . . . of the plurality of heat pipes 11, 11, 11 . . . can directly contact the heat-generating element 101, the thermal resistance when the heat is transferred from the heat-generating element 101 to the heat receiving portions 22 of the heat pipes 11 can be further reduced, with respect to all of the plurality of heat pipes 11, 11, 11 . . .

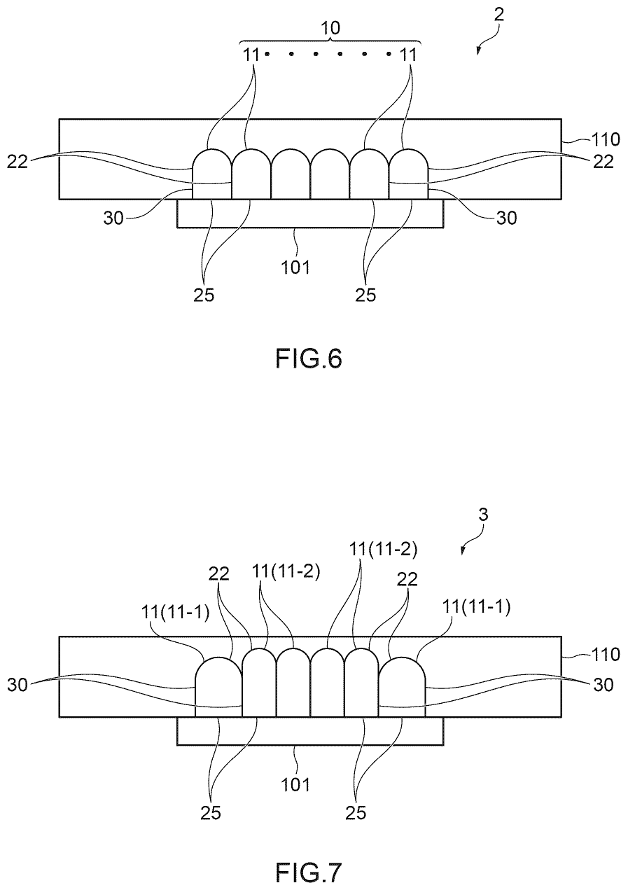

Next, a heat sink according to a second embodiment of the present disclosure will be described with reference to the accompanying drawing. The heat sink according to the second embodiment is similar to the heat sink according to the first embodiment in terms of main components, and hence the same components as those of the heat sink according to the first embodiment are described with use of the same reference characters. FIG. 6 is an explanatory view illustrating an outline of one end portion of the heat sink according to the second embodiment of the present disclosure from a front direction.

In the heat sink 1 according to the first embodiment, the heat pipe group 10 is formed by the eight heat pipes 11. However, instead of this, as illustrated in FIG. 6, in a heat sink 2 according to the second embodiment, a heat pipe group 10 is formed by six heat pipes 11.

In the heat sink of the present disclosure, the number of heat pipes 11 is appropriately selectable according to use conditions or the like of the heat sink such as a heat generation amount, a dimension and the like of the heat-generating element 101 as a cooling target. The heat sink 2 has an aspect in which the number of heat pipes 11 is made smaller than that in the heat sink 1 according to the first embodiment due to the use conditions such as the heat generation amount of the heat-generating element 101 as the cooling target being smaller, or the dimension of the heat-generating element 101 being smaller than that in the heat sink 1 according to the first embodiment, for example.

In the heat sink 2, similarly to the heat sink 1, a sectional shape in an orthogonal direction to a heat transporting direction of the heat pipe 11 is a flat shape. In other words, a heat receiving portion 22 of the heat pipe 11 has a flattened portion 30 having a flat shape having a height direction and a thickness direction having a smaller dimension than a dimension in the height direction, and of the flattened portion 30, a section in the thickness direction is a flat segment 25.

In the heat sink 2 in which the number of heat pipes 11 is reduced to be smaller than that in the heat sink 1, as a result of the section of the heat receiving portion 22 facing the heat-generating element 101 being also the flat segment 25 that is flat along the extending direction of the heat-generating element 101, the heat-generating element 101 can also be stably connected to the flat segment 25 of the heat receiving portion 22, and hence, stability of thermal connection between the heat receiving portion 22 of the heat pipe 11 and the heat-generating element 101 can also be obtained without aid of a connecting/fixing member for the heat pipe 11, such as a heat receiving block. In the heat sink 2, the heat receiving portion 22 of the heat pipe 11 also directly contacts the heat-generating element 101. Therefore, in the heat sink 2, thermal resistance when the heat is transferred from the heat-generating element 101 to the heat receiving portion 22 of the heat pipe 11 can also be reduced.

Next, a heat sink according to a third embodiment of the present disclosure will be described with reference to the accompanying drawing. The heat sink according to the third embodiment is similar to the heat sinks according to the first and second embodiments in terms of main components, and hence the same components as those of the heat sinks according to the first and second embodiments are described with use of the same reference characters. FIG. 7 is an explanatory view illustrating an outline of one end portion of the heat sink according to the third embodiment of the present disclosure from a front direction.

In the heat sink 1 according to the first embodiment, in the heat receiving portions 22, 22, 22 . . . of the plurality of heat pipes 11, 11, 11 . . . , all the sectional shapes in the radial direction of the heat receiving portions 22, 22, 22 . . . are substantially the same. However, instead of this, as illustrated in FIG. 7, a heat sink 3 according to the third embodiment provides an aspect in which sectional shapes in a radial direction in the heat receiving portions 22, 22, 22 . . . of the plurality of heat pipes 11, 11, 11 . . . are different among the plurality of heat pipes 11, 11, 11 . . .

The heat sink 3 provides an aspect in which the plurality of heat pipes 11, 11, 11 . . . are formed by first heat pipes 11-1 and second heat pipes 11-2, and heat transport characteristics of the first heat pipe and heat transport characteristics of the second heat pipe are different. Specifically, in the heat sink 3, the plurality of heat pipes 11, 11, 11 . . . include the first heat pipes 11-1 of which sectional shapes in the radial direction in the heat receiving portions 22 are first shapes, and the second heat pipes 11-2 of which sectional shapes in the radial direction in the heat receiving portions 22 are second shapes different from the first shapes. From the above, in the heat sink 3, there are a plurality of types (two types) of sectional shapes in the radial direction of the heat pipes 11 in the heat receiving portions 22. In the heat sink 3, two of the first heat pipes 11-1, and four of the second heat pipes 11-2 are included in the six heat pipes 11 11, 11 . . . for convenience of explanation.

In the heat sink 3, the heat receiving portions 22 of the first heat pipes 11-1 and the heat receiving portions 22 of the second heat pipes 11-2 are disposed parallelly along the radial direction of the heat pipe 11, and the heat receiving portions 22 of the first heat pipes 11-1 are disposed in a more outward direction than the heat receiving portions 22 of the second heat pipes 11-2. From the above, the heat receiving portions 22 of the second heat pipes 11-2 are fitted between the heat receiving portions 22 of the first heat pipes 11-1.

In the heat sink 3, an area of a section in a radial direction of the first heat pipe 11-1 is larger than an area of a section in a radial direction of the second heat pipe 11-2. Therefore, heat transport characteristics of the first heat pipe 11-1 are higher than heat transport characteristics of the second heat pipe 11-2. An aspect in which a sectional shape in a radial direction in the heat receiving portion 22 of the first heat pipe 1-1 is wider and at a lower height than a sectional shape in a radial direction in the heat receiving portion 22 of the second heat pipe 11-2 is provided.

In the heat sink 3, in the first heat pipe 11-1, a sectional shape in an orthogonal direction to a heat transporting direction of the first heat pipe 11-1 is also a flat shape similarly to the heat sinks 1 and 2. In other words, the heat receiving portion 22 of the first heat pipe 11-1 has a flattened portion 30 having a flat shape having a height direction and a thickness direction that has a dimension smaller than a dimension in the height direction, and of the flattened portion 30, a section in the thickness direction is a flat segment 25. In the second heat pipe 11-2, a sectional shape in an orthogonal direction to a heat transporting direction of the second heat pipe 11-2 is a flat shape. In other words, the heat receiving portion 22 of the second heat pipe 11-2 has a flattened portion 30 having a flat shape having a height direction and a thickness direction having a dimension smaller than a dimension in the height direction, and of the flattened portion 30, a section in the thickness direction is a flat segment 25.

In the heat sink 3, it is possible to adjust a difference of the heat transport characteristics of the first heat pipe 11-1 and the second heat pipe 11-2. Therefore, even when temperature irregularities such as hot spots occur to the heat-generating element 101, excellent cooling characteristics can be exhibited to the heat-generating element 101 where the temperature irregularities occur while the heat receiving portions 22 are miniaturized by thermally connecting the first heat pipe 11-1 having relatively high heat transport characteristics to sections of hot spots, and thermally connecting the second heat pipe 11-2 having relatively low heat transport characteristics to the section that is not the hot spot.

In the heat sink 3 including the heat pipes 11 having different sectional shapes in the radial direction in the heat receiving portions 22, as a result of the section of the heat receiving portion 22 that faces the heat-generating element 101 being also the flat segment 25 that is flat along the extending direction of the heat-generating element 101, the heat-generating element 101 can also be stably connected to the flat segment 25 of the heat receiving portion 22, and hence stability of thermal connection between the heat receiving portion 22 of the heat pipe 11 and the heat-generating element 101 can also be obtained without aid of a connecting/fixing member for the heat pipe 11 such as a heat receiving block. In the heat sink 3, the heat receiving portion 22 of the heat pipe 11 directly contacts the heat-generating element 101. Therefore, in the heat sink 3, the thermal resistance when the heat is transferred to the heat receiving portion 22 of the heat pipe 11 from the heat-generating element 101 can also be reduced.

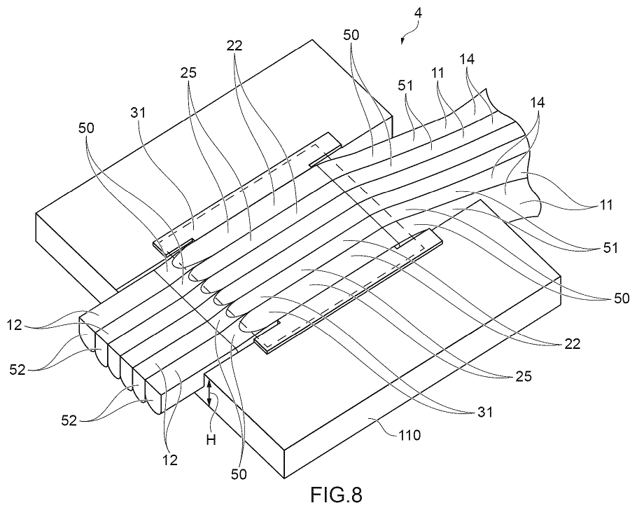

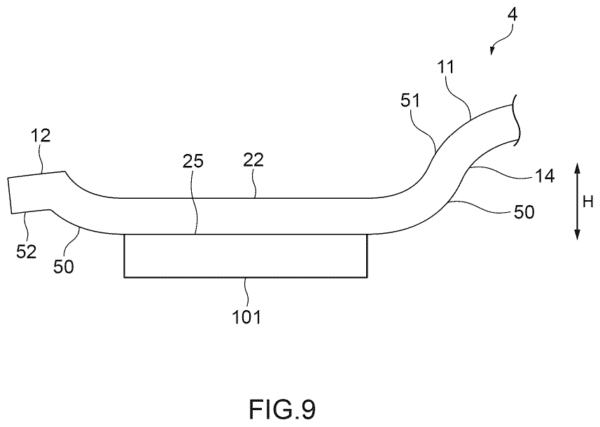

Next, a heat sink according to a fourth embodiment of the present disclosure will be described with reference to the accompanying drawings. The heat sink according to the fourth embodiment is similar to the heat sinks according to the first to third embodiments in terms of main components, and hence the same components as those of the heat sinks according to the first to third embodiments are described with use of the same reference characters. FIG. 8 is an explanatory view illustrating an outline of a bottom surface of one end portion of the heat sink according to the fourth embodiment of the present disclosure. FIG. 9 is an explanatory view illustrating a stretching state of a heat pipe included in the heat sink according to the fourth embodiment of the present disclosure.

As illustrated in FIGS. 8 and 9, in a heat sink 4 according to the fourth embodiment, the heat pipe 11 has a bent portion 50 that is bent in a direction to be away from the flat segment 25, in a section 51 that is other than the heat receiving portion 22 and extends in the longitudinal direction of the heat pipe 11 from the heat receiving portion 22. In the heat sink 4, the bent portion 50 is provided in a vicinity of a boundary portion of the heat receiving portion 22 and a heat insulating portion 14. The bent portion 50 has a stepped shape and is a stepped portion. The bent portion 50 having a stepped shape is bent along a height direction H of the heat receiving portion 22 of the heat pipe 11.

From the above, in the heat sink 4, the heat insulating portion 14 of the heat pipe 11 stretches toward a position higher than the heat receiving portion 22 of the heat pipe 11, and a heat dissipation portion (not illustrated) of the heat pipe 11 is disposed at a position higher than the heat receiving portion 22 of the heat pipe 11. The heat sink 4 further has a bent portion 50 bent in a direction to be away from the flat segment 25 also in a vicinity of a tip 52 of one end portion 12 of the heat pipe 11. The bent portion 50 in the vicinity of tip 52 of the one end portion 12 also has a stepped shape and is also a stepped portion. The bent portion 50 having a stepped shape in the vicinity of tip 52 of end portion 12 is also bent along a height direction H of the heat receiving portion 22 of the heat pipe 11. Therefore, tip 52 of the one end portion 12 is disposed at a position higher than the heat receiving portion 22 of the heat pipe 11.

In the heat sink 4, of the heat pipe 11, a section of the flat segment 25 facing the heat-generating element 101 protrudes toward the heat-generating element 101. Meanwhile, tip 52 of end portion 12, the heat insulating portion 14 and the heat dissipation portion that do not face the heat-generating element 101 are provided at positions further away from the section of the flat segment 25 facing the heat-generating element 101 in the height direction H.

In the heat sink 4, cutting is also applied to flat segment 25, and therefore, the flat segment 25 has a cut portion 31. Of a bottom surface of a cover member 110, which is positioned on a same plane as the flat segment 25, the cut portion 31 extends to a partial region of the bottom surface of the cover member 110 continuously with the cut portion 31 of the heat pipe 11.

In the heat sink 4, the heat pipe 11 has the bent portion 50 that is bent in the direction to be away from the flat segment 25, in the section 51 that is other than the heat receiving portion 22, and extends in the longitudinal direction of the heat pipe 11 from the heat receiving portion 22, and has the bent portion 50 bent in the direction to be away from the flat segment 25 in the vicinity of the tip 52 of the one end portion 12. Therefore, even when the heat-generating element 101 is installed in a narrow space, the heat pipe 11 can stretch to the section other than the heat receiving portion 22 while avoiding the narrow space. Therefore, the heat sink 4 can also exhibit excellent cooling characteristics for the heat-generating element 101 installed in the narrow space.

Even in the heat sink 4 in which the bent portion 50 having the stepped shape is formed in the heat pipe 11, the section of the heat receiving portion 22 that faces the heat-generating element 101 is the flat segment 25 that is flat along the extending direction of the heat-generating element 101, and hence the heat-generating element 101 can be stably connected to flat segment 25 of the heat receiving portion 22. Therefore, stability of thermal connection between the heat receiving portion 22 of the heat pipe 11 and the heat-generating element 101 can be obtained without aid of a connecting/fixing member for the heat pipe 11 such as a heat receiving block. In the heat sink 4, the heat receiving portion 22 of the heat pipe 11 also directly contacts the heat-generating element 101. Therefore, in the heat sink 4, thermal resistance when the heat is transferred to the heat receiving portion 22 of the heat pipe 11 from the heat-generating element 101 can also be reduced, and hence excellent cooling characteristics can also be exhibited to the heat-generating element 101.

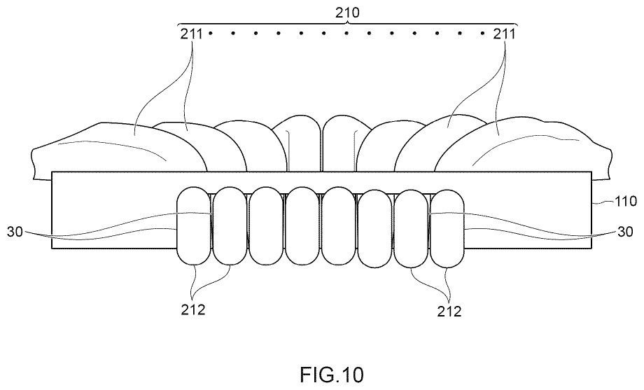

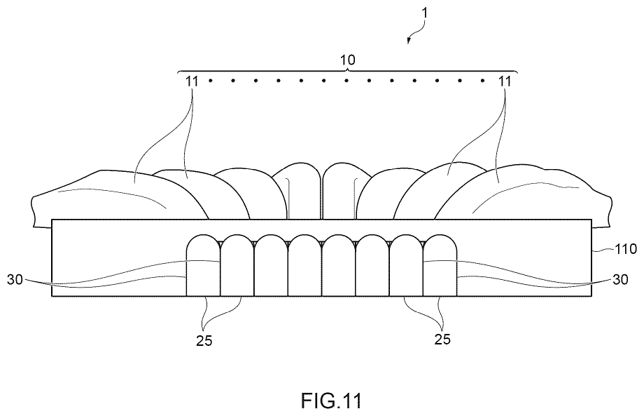

Next, a method for forming the flat segment 25 at the heat receiving portion 22 of the heat pipe 11 will be described. Here, the method for forming flat segment 25 will be described by using the heat sink 1 according to the first embodiment. FIG. 10 is an explanatory view illustrating a state before forming the flat segment at the heat receiving portion of the heat pipe included in the heat sink. FIG. 11 is an explanatory view of the heat sink of the present disclosure, illustrating a state after the flat segment is formed at the heat receiving portion of the heat pipe included in the heat sink.

First, a heat pipe in which a sectional shape in the radial direction is a circular shape is prepared, and a heat pipe 211 having a flattened portion 30 is produced by applying flattening to at least a portion corresponding to the heat receiving portion. Next, as illustrated in FIG. 10, the heat pipe 211 having the flattened portion 30 is inserted into the cover member 110, and a heat pipe group 210 including a plurality (in FIG. 10, eight) of heat pipes 211, 211, 211 . . . is formed. At this time, a section of the heat pipe 211 facing the heat-generating element has a protrusion portion 212 in which a part of the flattened portion 30 protrudes from a bottom surface of the cover member 110.

Next, as illustrated in FIG. 11, flattening is applied to the protrusion portion 212 of the heat pipe 11, and flat segment 25 is formed. As the flattening, plastic deformation treatment that plastically deforms the protrusion portion 212 in a cover member 110 direction can be listed, for example. By flattening, flat segment 25 and the bottom surface of the cover member 110 are positioned on a substantially same plane. By the above-described process, the heat sink 1 in which the flat segment 25 is formed at the heat receiving portion 22 of the heat pipe 11 can be produced.

Next, other embodiments of the heat sink of the present disclosure will be described hereinafter.

In each of the above-described embodiments, of the heat receiving portion of the heat pipe, the section facing the heat-generating element is the flat segment. However, of the heat receiving portion of the heat pipe, the flat segment may be formed at only the section facing the heat-generating element, the flat segment may be formed at only the entire heat receiving portion of the heat pipe, or the flat segment may be formed not only at the heat receiving portion of the heat pipe, but also at the section other than the heat receiving portion of the heat pipe.

In each of the above-described embodiments, the heat receiving portion of the heat pipe has the flattened portion having the flat shape in which the section in the thickness direction is the flat segment, but only the heat receiving portion of the heat pipe may have the above-described flattened portion, or not only the heat receiving portion of the heat pipe but also the section other than the heat receiving portion of the heat pipe may have the above-described flattened portion. In each of the above-described embodiments, the heat pipe has the flattened portion in which the section in the thickness direction is the flat segment, but as long as the flat segment is formed at the section facing the heat-generating element, of the heat receiving portion of the heat pipe, the shape in the radial direction of the heat pipe is not particularly limited, and may be the shape without having the flattened portion, instead of this.

The heat sink of the present disclosure is usable in a wide range of fields, and can exhibit excellent cooling performance to the heat-generating elements of high heat generation amount installed in a narrowed space. Therefore, the heat sink of the present disclosure can be used in, for example, a field where high-performance electronic components are used, such as a server used in a data center or the like.

What is claimed is:

1. A heat sink comprising a heat pipe having a heat receiving portion adapted to be thermally connected to a heat-generating element, and a heat exchanging portion thermally connected to a heat dissipation portion of the heat pipe,
wherein the heat pipe has an internal space communicating from the heat receiving portion to the heat dissipation portion, and filled with a working fluid,
a section facing the heat-generating element of the heat receiving portion comprises a flat segment that is flat along an extending direction of the heat-generating element,
the flat segment directly contacts the heat-generating element, and
a plurality of the heat pipes is provided and wherein heat transport characteristics of a first heat pipe are different from heat transport characteristics of a second heat pipe.

2. The heat sink according to claim 1, wherein a plurality of the heat pipes is provided, the plurality of the heat pipes include the first heat pipe in which a sectional shape in a radial direction in the heat receiving portion is a first shape, and the second heat pipe in which a sectional shape in a radial direction in the heat receiving portion is a second shape that is different from the first shape.

3. The heat sink according to claim 2, wherein the flat segment extends along a heat transport direction of the heat pipe and a radial direction of the heat pipe.

4. The heat sink according to claim 1, wherein the flat segment extends along a heat transport direction of the heat pipe and a radial direction of the heat pipe.

5. The heat sink according to claim 1, wherein the flat segment has a cut portion that is cut.

6. The heat sink according to claim 5, wherein as a result of the cut portion extending to a corner portion in a radial direction of the heat pipe, at least a part of a rounded portion formed at the corner portion is cut.

7. The heat sink according to claim 1, wherein the heat receiving portion has a flattened portion of which a sectional shape in an orthogonal direction to a heat transport direction of the heat pipe is a flattened shape, and which has a height direction and a thickness direction, and of the flattened portion, a section in the thickness direction has the flat segment.

8. The heat sink according to claim 7, wherein the flat segment of the section in the thickness direction of the flattened portion has a cut portion that is cut.

9. The heat sink according to claim 1, wherein a plurality of the heat pipes is provided, the plurality of the heat pipes is disposed along a radial direction of the heat pipes, and flat segments of the plurality of the heat pipes are disposed on a same plane in the heat receiving portions.

10. The heat sink according to claim 2, wherein a plurality of the heat pipes is provided, the plurality of the heat pipes is disposed along a radial direction of the heat pipes, and flat segments of the plurality of the heat pipes are disposed on a same plane, in the heat receiving portions.

11. The heat sink according to claim 1, wherein a plurality of the heat pipes is provided, the plurality of the heat pipes is disposed along the radial direction of the heat pipes in the heat receiving portions, and the heat pipes which are adjacent directly contact each other in the heat receiving portions.

12. The heat sink according to claim 2, wherein a plurality of the heat pipes is provided, the plurality of the heat pipes is disposed along the radial direction of the heat pipes in the heat receiving portions, and the heat pipes which are adjacent directly contact each other in the heat receiving portions.

13. The heat sink according to claim 9, wherein all of the flat segments of the plurality of the heat pipes directly contact the heat-generating element.

14. The heat sink according to claim 10, wherein all of the flat segments of the plurality of the heat pipes directly contact the heat-generating element.

15. The heat sink according to claim 1, wherein the heat transport characteristics of the first heat pipe are higher than the heat transport characteristics of the second heat pipe.

16. The heat sink according to claim 2, wherein the heat transport characteristics of the first heat pipe are higher than the heat transport characteristics of the second heat pipe.

17. The heat sink according to claim 1, wherein a heat receiving portion of the first heat pipe and a heat receiving portion of the second heat pipe are disposed along a radial direction of the heat pipes, and the heat receiving portion of the first heat pipe is disposed in an outward direction relative to the heat receiving portion of the second heat pipe.

18. The heat sink according to claim 2, wherein a heat receiving portion of the first heat pipe and a heat receiving portion of the second heat pipe are disposed along a radial direction of the heat pipes, and the heat receiving portion of the first heat pipe is disposed in an outward direction relative to the heat receiving portion of the second heat pipe.

19. The heat sink according to claim 1, wherein the heat pipe has a bent portion that is bent in a direction away from the flat segment, in a section that is other than the heat receiving portion and extends in a longitudinal direction of the heat pipe from the heat receiving portion.

20. The heat sink according to claim 2, wherein the heat pipe has a bent portion that is bent in a direction away from the flat segment, in a section that is other than the heat receiving portion and extends in a longitudinal direction of the heat pipe from the heat receiving portion.
